(19) United States
(12) Patent Application Publication
(10) Pub. No.: US 2008/0129302 A1
(43) Pub. Date: Jun. 5, 2008

(54) Microelectromechanical Electric Potential Sensor

(76) Inventors: Cyrus Shafai, Winnipeg (CA); Behraad Bahreyni, Cambridge, MA (US)

Correspondence Address: ADE & COMPANY INC., 2157 Henderson Highway, WINNIPEG, MB, R2G1P9, omitted

(21) Appl. No.: 11/947,904

(22) Filed: Nov. 30, 2007

Related U.S. Application Data
(60) Provisional application No. 60/867,897, filed on Nov. 30, 2006.

(51) Int. Cl. G01R 29/12

(52) U.S. Cl. 324/458

(57) ABSTRACT

An electrical potential sensor device comprises sensor electrodes arranged to measure a voltage based on a change in electrical charge induced in the sensor electrodes by exposure to an electrical potential of a source to be measured. An electro-thermally operated mechanism, adjacent to the sensor electrodes, is movable between a first position in which only first ones of the sensor electrodes are exposed to the electrical potential of the source to be measured and other sensor electrodes are shielded from the electrical potential, and a second position in which other ones of the sensor electrodes are exposed to the electrical potential and the first ones are substantially shielded from the electrical potential. A controller combines the output from the two sets of electrodes which are alternately exposed to the electrical potential to calculate a resulting measured/sensed voltage or measured/sensed electrical potential of the device.

This application claims priority to U.S. Provisional Application Ser. No. 60/867,897, filed Nov. 30, 2006.

### FIELD OF INVENTION

The present invention relates in general to a novel microelectromechanical electric field/potential sensor actuated by a electrothermal mechanism, and the application thereof.

### BACKGROUND OF THE INVENTION

It is necessary to measure the electric fields or potential in diverse applications ranging from applications in meteorology, mass spectroscopy, image formation control, biomedicine, power line monitoring, to cathodic protection monitoring for underground pipelines and alike.

Electric field mills (EFM) are the most common type of electric field or potential sensors (EFS), and many different types of EFMs are used. For example, the rotating vane type EFM has been the instrument of choice in many applications for atmospheric science and electric power systems, but such typical EFMs are bulky, expensive, power consuming, and require frequent maintenance.

More recently, miniature-scale EFSs based on microelectromechanical systems (MEMS) technology have been developed which are smaller, lighter, and more versatile, compared to the typical macroscale EFMs mentioned above. Correspondingly, the miniature EFSs are relatively more suitable for applications where electric field has fine spatial detail and spatial resolution is desired.

One type of such microelectromechanical EFSs (MEFS) is a variable capacitive coupling electric field/potential MEFS, and the basic operating principle for such an MEFS has been described in Hsu, C. H. and Muller, R. S., Solid State Sensors and Actuators, 1991, Digest of Technical Papers, Transducers, pp. 659-662, 1991; Horenstein , M. N. and Stone, P. R., “A microaperture electrostatic field mill based on MEMS technology,” Journal of Electrostatics, vol. 5152, pp. 515-521, May 2001; C. Peng, X. Chen, Q. Bai, L. Luo, and S. Xia, “A novel high performance micromechanical resonant electrostatic field sensor used in atmospheric electric field detection,” in Proceedings of the 19th IEEE Micro ElectroMechanical Systems Conference, MEMS 2006, Istanbul, Turkey, January 2006, pp. 698-701; U.S. Pat. No. 6,965,239; U.S. Pat. No Application No. 2006/0008284.

In brief, the operation of such an MEFS is based on using a grounded microshutter (or shielding electrode) to repeatedly shield and expose fixed sensor electrode(s), whereby exposing the sensor electrode(s) to the electric field results in a transfer of charges to the electrodes while shielding them discharges the sensor electrode(s). For the microshutter, MEFMs use a perforated plate which is electrically grounded through its mechanical support. The sensor electrode(s) are patterned over an insulating layer on substrate. Preferably, two sets of electrodes are often used for differential measurements which are exposed alternatively to the field.

In the past, the reciprocating movement of the grounded microshutter (or shielding electrode) has been actuated (or driven) by means such as capacitor-coupling based inter-digitated comb drives using electrostatic forces (as exemplified in U.S. Pat. No. 6,965,239) or apparatuses relying on a combination of a magnet and an electrically-conductive microshutter using electromagnetic forces (as exemplified in U.S. Pat. No. 6,177,800).

However, these conventional actuation means suffer from several distinct disadvantages. For example, large operating voltages (25 to 100V are required for the inter-digitated comb drives to produce the required displacements of the microshutter. Besides the difficulties with generating such voltages at the operating frequencies of micromachined devices, such large actuation voltages, as well as the fields associated with the electromagnetic drives, pose difficulties in taking measurements as not only they appear as interference at the output but they also modify the electric field distribution in the vicinity of the sensor electrode, thereby negatively impacting sensor sensitivity as well as accuracy.

### SUMMARY OF THE INVENTION

In view of the foregoing disadvantages of the prior art, the present invention relates to a new and improved MEFS-type electric field/potential sensor. Using an electrothermal actuator, a micro-electro-mechanical electric field/potential sensor may be produced which may enable lower power consumption as well as improved sensitivity and accuracy due to reduced interference.

According to one aspect of the present invention, there is provided an electrical potential sensor device for measuring electrical potential of a source to be measured, the device comprising:

at least one sensor electrode arranged to measure a voltage based on a change in electrical charge induced in said at least one sensor electrode by exposure to the electrical potential of the source to be measured;

a mechanism adjacent to said at least one sensor electrode which is movable between a first position in which said at least one sensor electrode is exposed to the electrical potential of the source to be measured and a second position in which said at least one sensor electrode is substantially shielded from the electrical potential of the source to be measured in relation to the first position; and

at least one actuator arranged to operate the mechanism between the first and second positions;

said at least one actuator comprising an electrothermal actuator.

In a preferred embodiment, the electrothermal actuator comprises is an actuator which is responsive to a temperature differential which is arranged to be induced by an alternating electrical current.

The mechanism may comprise a movable shutter having openings therein, the openings being aligned with said at least one sensor electrode only in the first position of the mechanism.

In the illustrated embodiments said at least one sensor electrode comprises first electrodes and there are also provided auxiliary sensor electrodes comprising second electrodes similarly arranged to measure the voltage based on a change in electrical charge induced in the electrode by exposure to the electrical potential of the source to be measured. In this instance, the mechanism may be arranged such that only the first electrodes are exposed to the electrical potential of the source to be measured in the first position and that only the second electrodes are exposed to the electrical potential of the source to be measured in the second position of the mechanism.

The sensor electrodes which are arranged to be exposed to the electrical potential of the source to be measured in the first position are preferably arranged to measure a first voltage and the sensor electrodes which are arranged to be exposed to the electrical potential of the source to be measured in the second position are preferably arranged to measure a second voltage in which the first and second voltages are 180° out-of-phase with one other. In this instance, preferably there is provided a differential amplifier arranged to produce a single measured output voltage from the first and second voltages subtracted from one another.

The mechanism may be supported for movement relative to said at least one sensor electrode in a direction of movement of an output of the actuator.

A pair of actuators may be supported on respective opposite sides of the mechanism in which the pair of actuators are electrically driven by respective oppositely phased alternating currents. In this instance, the mechanism may be ungrounded.

The electrothermal actuator may be coupled to the mechanism through a lever which is coupled to the mechanism by a loop member, in which the lever and the mechanism are connected at diametrically opposing sides of the loop member.

The electrothermal actuator may comprise a bent beam electrothermal actuator, including a simple bent-beam or a cascading bent-beam electrothermal actuator, or a plurality of bent beam electrothermal actuators in parallel with one another.

The device, including the mechanism and said at least one actuator, but with the exception of the sensor electrodes, may be surrounded by an electromagnetic shield, for example a Faraday cage, arranged to shield said mechanism and said at least one actuator from the electrical potential of the source.

Furthermore, the mechanism may be housed in a vacuum chamber maintained at a vacuum pressure.

In some embodiments, there may be provided a processor arranged to determine an electric field of the source to be measured using the voltage measured by said at least one sensor electrode.

The electric field/potential sensor of the present invention, which may lower power consumption, and improve sensitivity and accuracy according to some aspects of the present invention, typically comprises one or more sensor electrode(s) for measuring a voltage (electric potential) based on a change in electrical charge induced in said sensor electrode, capacitor modulating means for modulating a coupling capacitance between each sensor electrode and the electrical potential to be measured; and one or more driver(s) (actuator(s)) operatively associated with the capacitor modulating means, wherein each driver (actuator) comprises an electrothermal actuator. For example, the electric field/potential sensor is a comb-driven variable capacitive coupling electric field MEFS, and the capacitor modulating means comprises a grounded or ungrounded microshutter (or shielding electrode) that has fenestrations (openings therein for periodic alignment with the sensor electrodes) and is movable between a first position where said microshutter exposes said sensor electrode to the voltage (electric potential) to be measured through the openings and a second position where said microshutter covers at least a portion of said sensor electrode with respect to the voltage (electric potential) to be measured by misaligning the openings with the sensor electrodes.

In one embodiment, the electrothermal actuator for driving the grounded or ungrounded microshutter (or shielding electrode) of the MEFS between the first position and the second position is a simple bent-beam electrothermal actuator which includes a substrate having a surface (which may be the same surface on which the sensor electrode(s) is/are mounted), on which two anchor mounts are mounted and spaced from each other. The simple bent-beam generally comprises two thermal expansion beam elements joined in a substantially V-shaped pattern to form the bent-beam so that the two beam elements extend from the vertex or apex of the beam to opposing ends of the beam. The two thermal expansion beam elements, each have one terminus flexibly hinged to a respective one of the anchor mounts as referred to above, and the other terminus flexibly hinged to the other beam element at the vertex or apex to form the inwardly or outwardly (substantially V-shaped) bent beam extending between the two anchor mounts.

An actuator output beam element can in turn be attached to the vertex formed by the two hinging thermal expansion beam elements. Electrical current is passed through the thermal expansion beam elements between the anchor mounts to cause heating and expansion of the beam elements, causing the vertex hinging the pair of thermal expansion beam elements to be displaced inwardly or outwardly, and correspondingly displacing the actuator output beam element inwardly or outwardly along a driver axis. When the actuator output beam element is adjoined to the grounded or ungrounded microshutter (or shielding electrode), such inwardly and/or outwardly motion of the actuator output beam element is used to provide the required reciprocal displacements of the microshutter to induce capacitor modulation in which the displacements are oriented parallel in the direction of the driver axis.

In respect of the flexible hinging mechanisms suitable for adjoining the aforementioned beam elements, conventional compliant mechanisms, as may be represented by structures that deform elastically to transmit a force or displacement, are suitable for the present application, and preferably the thermal expansion characteristics of the material used for the compliant mechanism are compatible with the thermal expansion characteristics of the material of which the beam elements are made as well as those for the substrate surface.

In another embodiment, it should be readily apparent to a skilled person in the art that each such basic unit of the simple bent-beam actuator described above may be connected substantially in parallel with each other, for example via a common actuator output beam element with the vertices of the units oriented in the same direction, so to concertedly effect a greater displacement force. Similarly, it should also be readily apparent that displacement distance and force can also be controlled by altering the unit geometry such as the vertex angle, thermal expansion beam element length, expansion beam element thickness, width, etcetera. For instance, higher forces can be generated by placing bent-beam actuators in parallel and/or by increasing thermal expansion beam element thickness or width, whereas greater displacement distances can be generated by cascading the actuators.

For the setup of a cascaded electrothermal actuator, the basic anchored pair of thermal expansion beam elements forming a bent-beam remains, but in lieu of the thermal expansion beam elements flexibly hinged to each other to form a vertex or apex, they are instead flexibly hinged to a secondary (internal) set(s) of beam elements flexibly hinged to each other (and potentially to additional anchor mounts on the substrate surface) so to create secondary vertex(ices) which would be in this case flexibly hinged to the actuator output beam element and amplify the displacement thereof. The secondary (internal) set(s) of beam elements may themselves be heated to expand, or they could simply be non-heated beam elements angularly arranged to amplify displacement. The overall configuration of the cascaded bent-beam actuator, including the secondary (internal) set(s) of beam elements, may also be symmetrical or asymmetrical, depending on the vector, frequency, and magnitude, of the displacement desired.

The beam elements and the compliant mechanisms in the actuator of the present invention may be made using conventional MEMS manufacturing techniques (such as the MicroGEM process) using materials commonly used in MEMS such as polysilicon, p++ Si, and electroplated Ni. For instance, the thermal expansion coefficient of electroplated Ni is approximately four times higher than that of Si. It is important to note, however, that although a high thermal expansion coefficient may be desirable for larger displacements, compatibility with the thermal expansion coefficient of the substrate is essential to avoid excessive expansion mismatch and unwanted configurational shifting during each heat cycle.

In a further embodiment, the electrothermal actuator for driving the grounded or ungrounded microshutter (or shielding electrode) of the MEFS of the present invention is a bimorph actuator which, in contrast to the aforementioned bent-beamed actuators, purposefully relies on structural segments with differing thermal expansion coefficients and can effect rectilinear as well as curvilinear displacements depending on configuration. The simplest form of a bimorph actuator is a planar biomorph actuation beam element consisting of a silicon layer (strip) and a metallic layer (strip) bound adjacent to each other. When heated, the beam element bends due to the different thermal expansion coefficients of silicon and the metal. Aluminum is a commonly used metal in bimorph actuator. Another type of a bimorph actuator is a cantilever type bimorph actuator in which the different layers are spaced apart and the differential expansion of the layers is primarily effected through dimensional (rather than material) difference(s) of the layers.

According to another aspect of the present invention, there is provided a method of application and use of the MEFS of the present invention. In general, the applicability and utility of a MEFS with lower power consumption and improved sensitivity and accuracy are readily apparent in view of the diverse applications that require sensitive and/or spatial measurement of electric field or potential.

In one embodiment, the inventors contemplate the use of the MEFS of the present invention in controlling the charge on photoreceptors in xerographic type copiers/printers for electrostatic image control purposes. Details of the xerographic device and method of operation are generally known to those of ordinary skill in the art.

In another embodiment, the inventors also contemplate the use of the MEFS of the present invention in the electrical/gas utility setting for applications ranging from the monitoring and measurement of electric fields emitted by high voltage power conductors and electrical apparatuses, to the monitoring and measurement of cathodic protection potentials on natural gas pipeline systems. For example, the MEFS of the present invention can be used to measure the cathodic potential between gas line and ground so for continuous monitoring of metallic gas pipe corrosion and rate thereof.

In a further embodiment, the MEFS of the present invention is also useful for monitoring of atmospheric electrical fields and charges, for instance in detection of lightning storms and other weather systems.

Other features and advantages of the present invention will become apparent from the following detailed description. It should be understood, however, that the detailed description and the specific examples while indicating preferred embodiments of the invention are given by way of illustration only, since various changes and modifications within the spirit and scope of the invention will become apparent to those skilled in the art from this detailed description.

### BRIEF DESCRIPTION OF THE DRAWINGS

For a more detailed disclosure of the invention and for further objects and advantages thereof, reference is to be had to the following description taken in conjunction with the accompanying drawings, in which:

FIG. 1 is a simple diagrammatic illustration of the basic operating principles of a microelectromechanical variable capacitive coupling electric field/potential sensor.

FIG. 2a is a top plan view of the microelectromechanical variable capacitive coupling electric field MEFS according to a first illustrated embodiment.

FIG. 2b is a simple diagrammatic illustration of an example of a cascaded bent-beam electrothermal actuator.

FIG. 3 is an enlarged top plan view of the electrothermal actuator for the microelectromechanical variable capacitive coupling electric field MEFS according to the first illustrated embodiment.

FIG. 4a is a simple diagrammatic illustration of the electronic circuitry for driving the electrothermal actuator according to the first illustrated embodiment.

FIG. 4b is a simple diagrammatic illustration of the sensor electrode circuitry according to the first illustrated embodiment.

FIG. 4c is a simple diagrammatic illustration of the measurement setup for the sensor electrode circuitry according to the first illustrated embodiment.

FIG. 5 is a graphical illustration of the output spectrum of the sensor electrode after the differential transconductance pre-amplifier (gain=14MV/A).

FIG. 6 is a graphical illustration of response microelectromechanical variable capacitive coupling electric field MEFS according to the first illustrated embodiment to varying electric field/potential strengths.

FIG. 7 is a graphical illustration of variation of resonance frequency with actuation voltage.

FIG. 8 is a graphical illustration of variation of sensor response with actuation voltage under varying vacuum conditions.

### DETAILED DESCRIPTION OF THE INVENTION

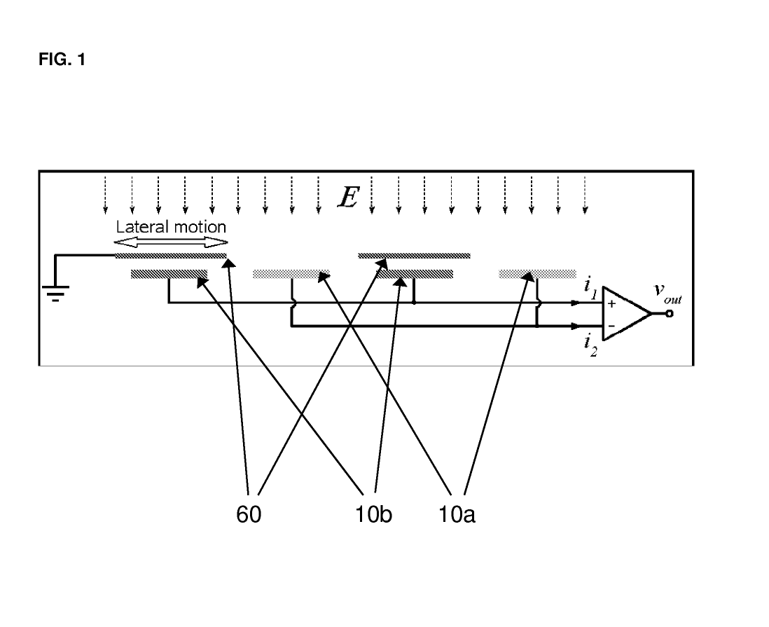

Referring to the accompanying drawings, FIG. 1 is a simple diagrammatic illustration of the basic operating principles of a microelectromechanical variable capacitive coupling electric field MEFS, illustrating the intermittent charging of the sensor electrodes 10a and 10b by the electric field as the microshutter (or shielding electrode) 60 repeatedly shields and exposes the sensor electrodes to the field. Note that the output current (signal) of electrodes 10a would be 180° asynchronous with the output current (signal) of electrodes 10b, both of which are correspondingly conveyed and manipulated downstream by conventional methods for calibration and calculation of electric field strengths.

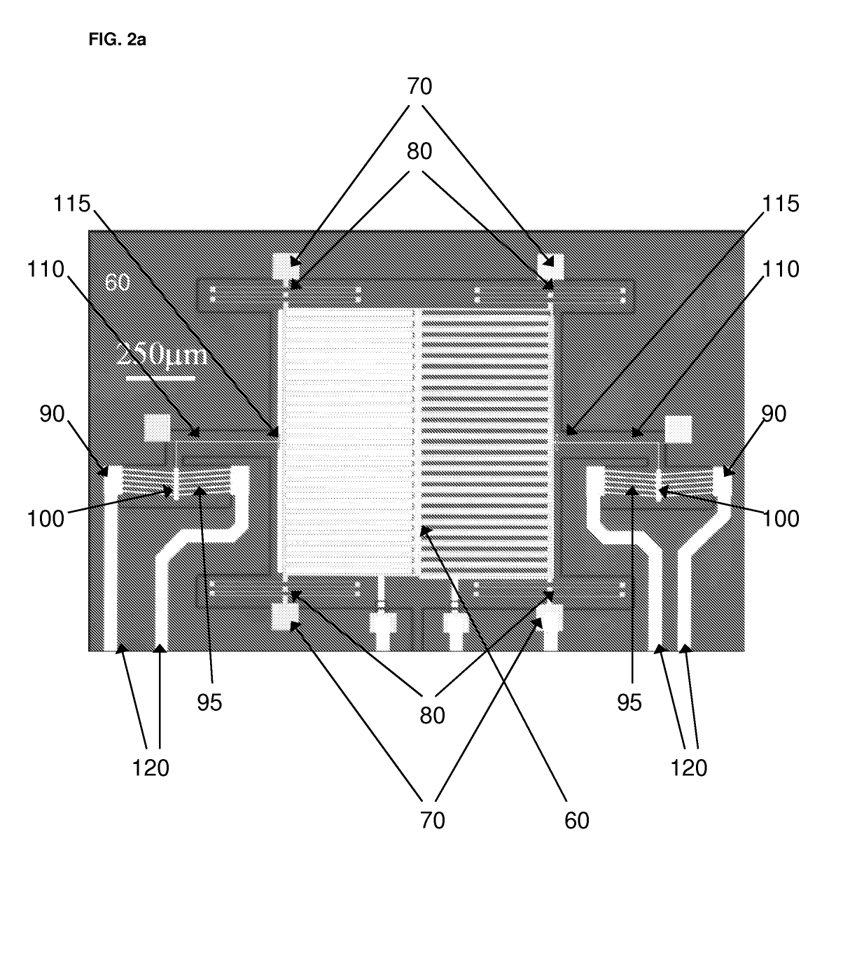

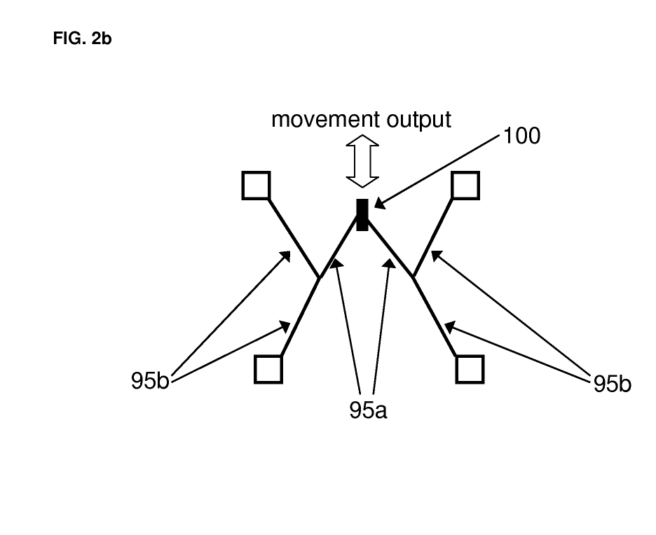

Referring to FIG. 2a, there is illustrated a microelectromechanical variable capacitive coupling electric field MEFS setup according to the present invention generally indicated by reference numeral 50.

In this particular embodiment, the MEFS 50 generally comprises two rows of sensor electrode(s) that are placed under (and superimposed in the present drawing by) a microshutter 60 comprising correspondingly two rows of fenestrations. The microshutter generally has a planar body, and each fenestration of the microshutter comprises an opening in the body which is configured and positioned to match each sensor electrode so that the microshutter can oscillate between a first position where said microshutter exposes substantially said sensor electrode to the voltage (electric potential) to be measured and a second position where said microshutter covers at least a portion of said sensor electrode with respect to the voltage (electric potential) to be measured. For integrity and stability, the microshutter 60 is in the present instance anchored to four substrate surface mounts 70 each via microspring 80.

The sensor electrodes 10 comprise a first set 10a and a second set 10b of sensor electrodes arranged to be alternately exposed to the electrical potential to be measured. The microshutter 60 comprises a movable shutter having openings therein arranged such that the openings are aligned with only the first set of sensor electrodes so as to shield the second set of sensor electrodes in one position of the shutter, while being aligned with only the second set of sensor electrodes so as to shield the first set of sensor electrodes in the other position of the shutter.

In order to actuate the oscillatory displacement of the microshutter 60 between the aforementioned first and second positions, two electrothermal actuators 90 are positioned adjacently on each side of the microshutter 60.

In the preferred embodiments, the electrothermal actuators 90 comprise bent beam electrothermal actuators.

In some embodiments, the actuators may comprise a simple bent beam electrothermal actuator. A simple bent beam electrothermal actuator generally comprises two thermal expansion beam elements joined with one another in a substantially V-shaped pattern in which the beam elements extend outwardly from an apex or vertex of the bent beam to opposing ends of the bent beam. The ends of the beam are support on respective anchors so that the apex or vertex is linearly displaced with thermal expansion and contraction of the beam elements when the beam elements are symmetrical and formed of similar material.

In other embodiments, each actuator may comprise a plurality of bent beams in parallel with one another in which the apexes of all of the bent beams are commonly joined with one another to form a common actuator output movement.

Each electrothermal actuator 90 in the illustrated embodiment comprises five pairs of simple thermal expansion beam elements 95 arranged in parallel to each other, and vertices of such thermal expansion beam elements 95 are flexibly hinged to a common actuator output beam element 100.

In turn, the actuator output beam element 100 of each electrothermal actuator 90 is fixably attached for flexing movement via a lever 110 to either side of the microshutter 60 to actuate displacement of microshutter 60.

The lever 110 is flexibly hinged to anchor mounts on the substrate to improve integrity and stability. The output beam of the driver is coupled to the lever 110 between the anchor mounts and the microshutter 60.

A loop 115 can be introduced along the lever 110 in the proximity of the point where the lever is attached to the microshutter 60. This loop 115, when connected between the lever and the microshutter at diametrically opposed sides of the loop, relaxes the statical boundary conditions at the junction of the actuator output beam element 100 and microshutter 60 and allows for easier pivoting at that point and increases displacement of microshutter 60 by over 30% at same given drive input levels. The loop also accommodates for dimensional variations between the ends of a pair of opposed levers which are displaced through respective arc-shaped movements. In essence, a major advantage of inclusion of loop(s) 115 is to facilitate shutter reciprocation, thereby permitting reduction in power needed for actuating the reciprocal movement of the microshutter, hence the overall power consumption of the electric field/potential sensor.

In yet further embodiments, the actuators may comprise cascading electrothermal actuators. As exemplified in FIG. 2b, a cascading electrothermal actuator comprises a first bent beam 95a in a substantially V-shaped pattern defining an apex or vertex 100 and two opposed ends and at least one second bent beam 95b in a substantially V-shaped pattern defining an apex or vertex and two opposed ends in which said at least one second bent beam supports one of the ends of the first bent beam at an apex or of said at least one second bent beam. Each of the bent beams can again comprise two further thermal expansion beam elements extending outwardly from the respective apex or vertex to the respective opposed ends of the beam. In this arrangement, the second bent beam augments the displacement of the actuator output at the apex or vertex of the first bent beam when the beam elements are thermally expanded.

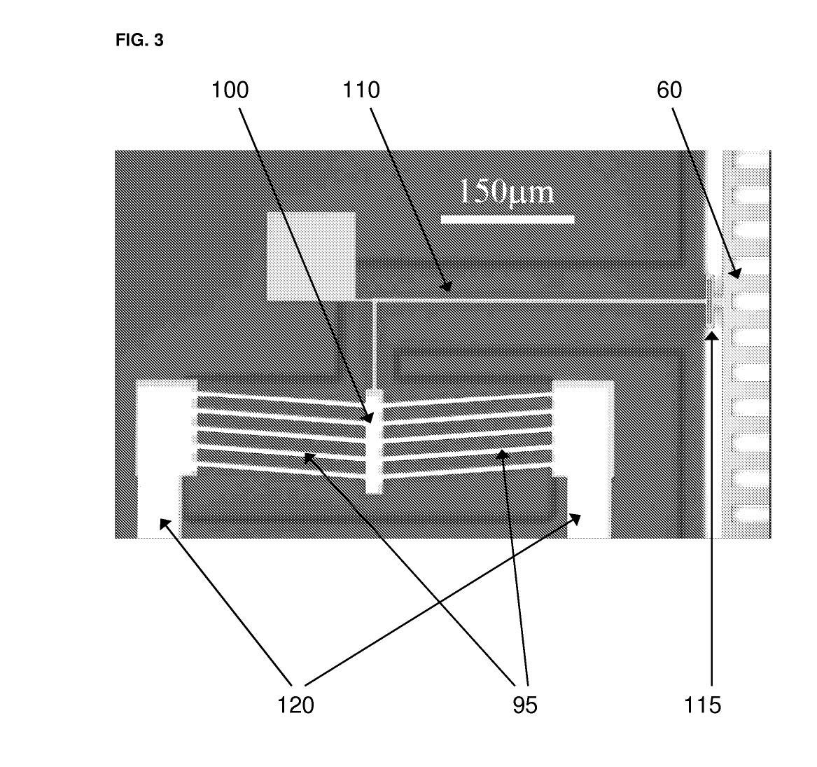

FIG. 3 is an enlarged view of the electrothermal actuator comprising the aforementioned five pairs of simple thermal expansion beam elements 95 arranged in parallel to each other, the common actuator output beam element 100, the lever 110 fixably attached to the microshutter 60, and in this instance the two contact points 120 for voltage to be applied to the thermal expansion beam elements 95. For the present embodiment, the substrate surface is a convention silicon board whilst the material used for the microshutter 60 is polysilicon.

In respect of the lever 110, whilst it is practicable that it can be made of a rigid, non-flexible, material to directly transfer/translate the displacement forces from the common actuator output beam element 100 to the microshutter 60, it is optional, but nonetheless important to note, that lever 110 can also be made of a marginally flexible material so that the displacement forces from the common actuator output beam element 100 can be amplified, or simply sustained, through resonance. For example, if the driving frequency is made to approximate the physical resonance frequency of lever 110 and microshutter 60, the inherent resonance can in part sustain the oscillatory displacement of the microshutter 60 thereby reducing electrical power needed for driving. Similarly, loop(s) 115 may also be used, by varying its physical and/or chemical properties, as a means to vary and selectively tune the natural resonant frequency of the oscillatory displacement of the microshutter 60 depending on application,

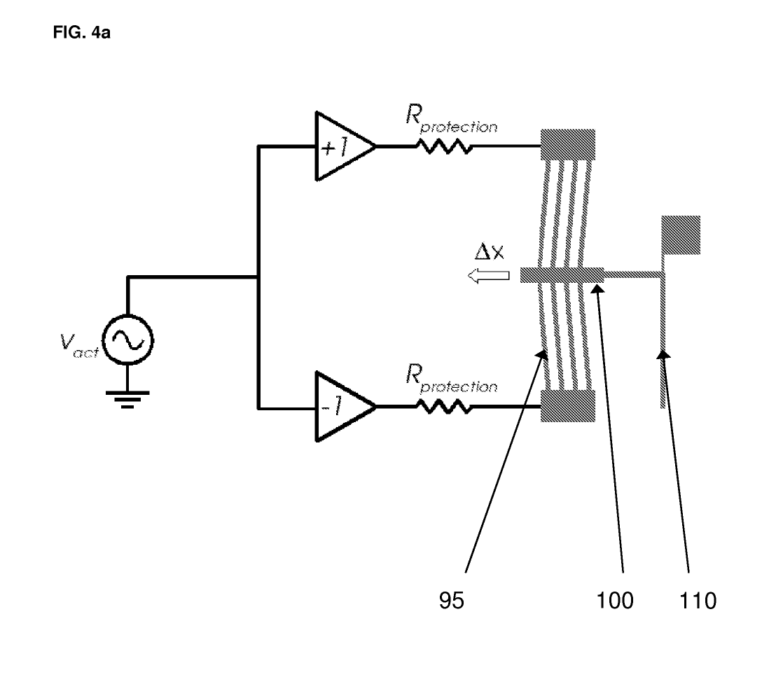

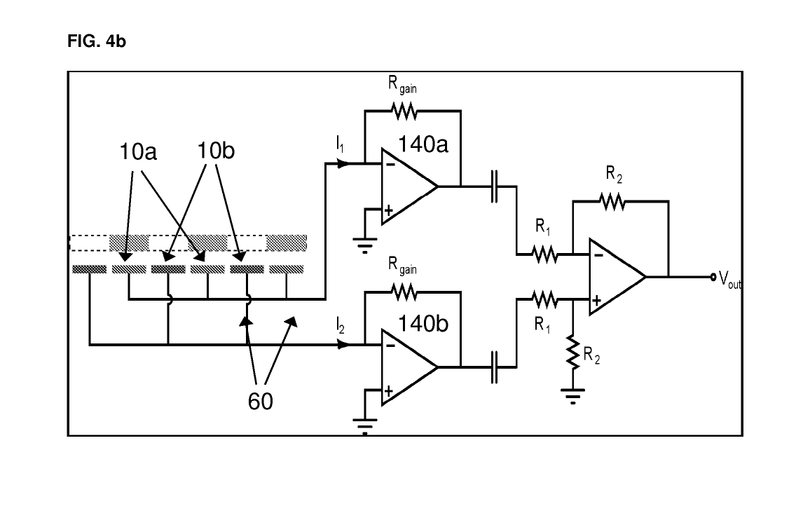

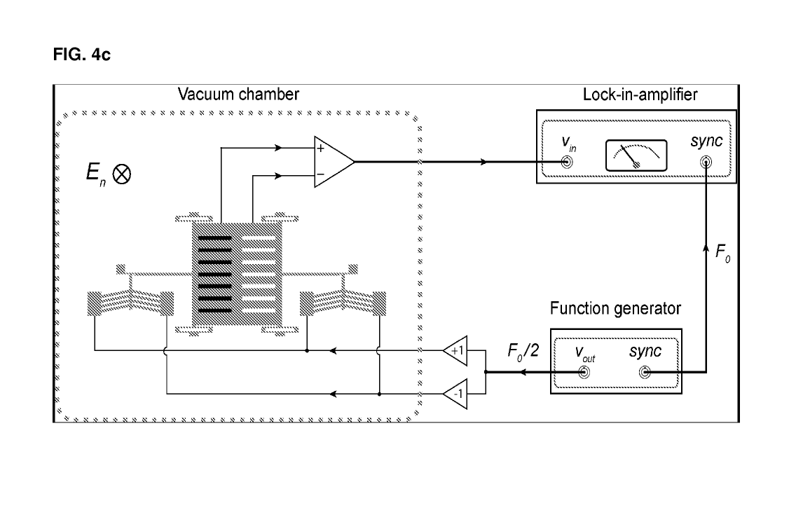

Referring to FIG. 4a, more specific information in respect of driving the electrothermal actuator vis-a-vis the MEFS setup according to the present invention is provided. For the particular embodiment described, the source used to drive each electrothermal actuator can range from 62.5 mV to 0.2V injected as alternating current (a.c.) at circa 3,400 Hz. Evidently in this setup, two thermal expansion cycles occur per 360 degrees of a.c. injection. It is also important to note that in this embodiment, the two sinusoidal voltages applied to each of the actuators are applied differentially to each other, that is one of the actuators receives a negative peak voltage when the other actuator receives a positive peak voltage and vice versa. This is done so that the effects of the electric fields produced by the drive signals are minimized and to make the potential effect on the microshutter 60 almost zero, which obviates the need for shutter grounding.

From the perspective of the sensing circuitry, as shown in FIG. 4b, the setup can comprise a first set of at least one sensor electrode 10a and a second set of at least one auxiliary sensor electrode 10b. Under this arrangement, when microshutter 60 is moved to a position where its openings are aligned with sensor electrode(s) 10a, sensor electrode(s) 10a would be exposed to the electrical potential of the source to be measured, while the auxiliary sensor electrode(s) 10b are shielded by microshutter 60; and vice versa. The output currents of the two sets of sensor electrodes 10a and 10b are channeled to two transresistance amplifiers 140a and 140b respectively (each with R_{gain} of 1.2×10⁶ V/A in this instance), which convert the currents into two voltage signals. The resulting voltage signals, which by design are 180° out-of-phase or asynchronous with each other, are then subtracted from each other using a differential amplifier to produce a single voltage as the electrode sensor output.

For processing of such electrode sensor output, the measurement set-up is illustrated in FIG. 4c. Incidentally, FIG. 4c also illustrates the power source for generating the input drive voltages which in this instance is a conventional function generator. Note that the electrode sensor output depicted herein is input to a lock-in amplifier which in turn is connected to the function generator for synchronous actuation of the two electrothermal actuators 90 exemplified in this setup. Alternatively, it should be readily apparent to a skilled person in the art that power supply may be in other forms such as a fixed-width voltage pulse injections, which in this latter instance, only one thermal expansion cycle would occur per voltage pulse injection.

Referencing the aforementioned mV range of drive voltages used for electrothermal actuators in the present embodiment, it is important to note that same is in stark contrast to the significantly higher 25V to 100V requirements of, for example, electrostatic comb-drive actuators of the prior art. For a sensor design based on electrostatic actuators, the power consumption for the signal processing electronics alone would be higher due to the fact that employing electrostatic actuators require boost amplifiers to produce large drive voltages and filters to remove the interference from the drive signal.

As mentioned earlier, a problem with electric field/potential sensors is that electric field from the drive voltage applied to the shutter actuators interferes with the measured external field “En”. For this particular embodiment described, the use of thermal actuators, especially taking advantage of mechanical resonance, reduces the required actuation voltage/power levels (as described above) thereby minimizing interference. To further reduce input drive voltage requirement and sensor interference, the sensor electrode circuit, as illustrated in FIG. 4c, may be put inside a vacuum chamber. Encasing the sensor electrode circuit in a vacuum reduces air dampening on the microshutter setup thereby enabling it to reciprocate more freely based on its natural resonance needing only minimal external power input to aid the sustenance of same. However, it is important to note that if the sensor electrode circuit is encased in a vacuum, consideration must be given to accommodate passage of the electric field/potential to the actual sensor electrode(s), and that interpretative compensation may be required to account for any delay or reduction of such passage of the electric field/potential to the sensor electrode(s).

Yet further, the MEFS can also be encased a within a Faraday cage or other electromagnetic shielding means to further improve measurement sensitivity and accuracy by further reducing interference that results from any gradual charging of non-sensing components of the MEFS by the electric field/potential. Of course, as above, it is important to note that if the sensor electrode circuit is encased in shielding, consideration must again be given to accommodate passage of the electric field/potential to the actual sensor electrode(s), with corresponding interpretative compensation in signal processing as may be required.

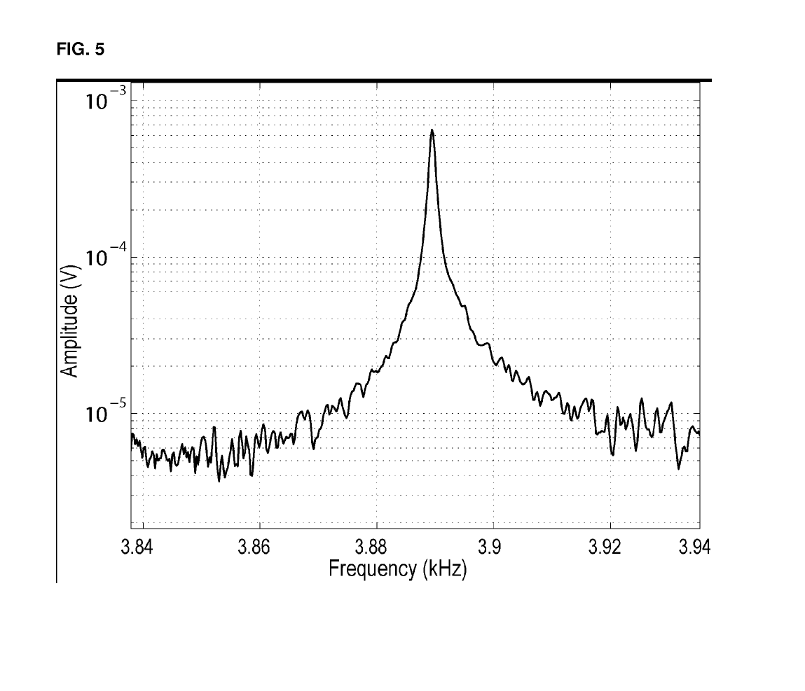

FIG. 5 illustrates the output spectrum of the sensor electrode inside a 5 kV/m field when driven by a 62.5 mV signal at a pressure of ˜20 mTorr. In this instance, the resonant frequency of the sensor is 3892.2Hz. Due to the quadratic relationship between the input voltage and produced heat, and therefore the displacement of microshutter 60, the output signal is at twice the frequency of the drive signal, and any interference due to the input voltage can be easily isolated using conventional bandpass and/or notch filtering means thereby improving resolution of the output signals and the sensitivity and accuracy of measurements. In other words, the current passed through beam elements of the actuators follows the sinusoidal curve of the input voltage and causing a heating and subsequent cooling cycle to occur at each positive and negative peak of the sinusoidal curve. As one set of electrodes is exposed to the electrical field to be measured at each of the heating and cooling portions of the cycle, the output signal generated by the two sets of electrodes together accordingly has twice the frequency of the input drive signal to the actuators.

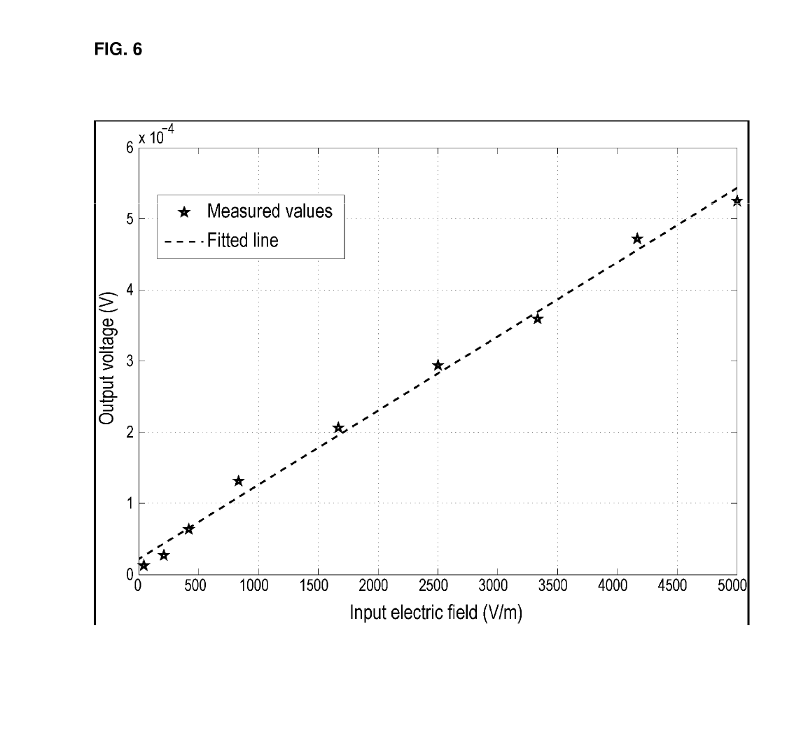

FIG. 6 shows the response of the MEFS according to this embodiment of the present invention to different electric field values. The minimum detectable field with this MEFS is about 42V/m which is, to the best of our knowledge, the best reported value for MEFSs, as compared to the limits of detection of conventional MEFS using other actuator mechanisms which are in the range of hundreds to thousands of V/m.

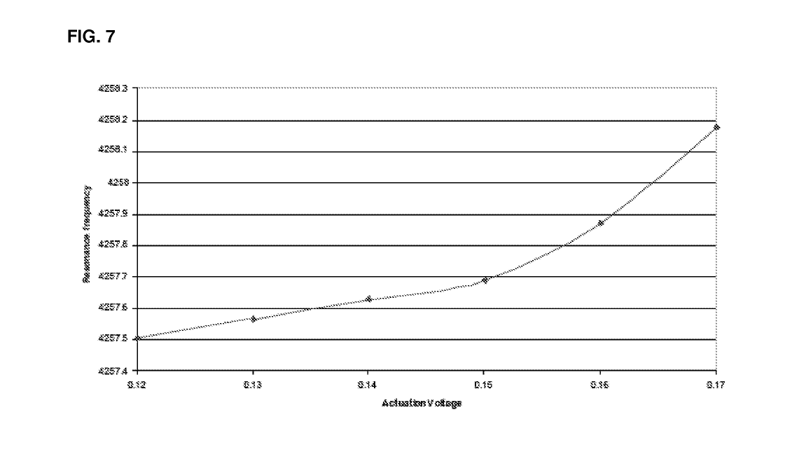

Based on the operating principles of a variable capacitive coupling-type MEFS, it should also be readily apparent to a skilled person in the art that the sensitivity of the MEFS as presented in the aforementioned embodiment can be modified and tailored to different applications involving different field strengths. Notwithstanding its lower field sensitivity as described above, the MEFS of the present invention can also be used to sense electric fields of thousands of V/m, and any electronic nonlinearities that may be encountered at higher field strengths may be overcome by using automatic gain control blocks to keep the amplifiers in their linear region. For sensing low field strengths, it is known that sensor sensitivity may be improved by increasing the frequency used in the variable capacitive coupling (i.e. frequency at which the microshutter 60 is driven). To increase frequency, various parameters of the present setup can be modified such as altering the dimensions and configurations of the microshutter 60. For instance, the thickness and size, and correspondingly the mass, of the microshutter 60 may be reduced to accommodate greater driving frequency (and use compensatorily a greater number of MEFS units); the width of the sensor electrodes fenestrations in the microshutter 60 may be reduced so to correspondingly reduce the magnitude of displacement required so that greater frequency may be used; encasing the MEFS 50, or part(s) thereof, in a vacuum to reduce friction and drag as compared to when same is/are surrounded by air; and/or use thermal expansion beam elements made of a material with greater thermal expansion coefficient so that smaller thermal gains/heat cycles are needed to achieve the same displacement desired. FIG. 7 illustrates an example of how an increase in actuation voltage affects resonant frequency of the microshutter under 19 mTorr vacuum condition. Of course, it should be readily apparent to a skilled person in the art that the profile of this relationship can be tuned to different frequency range(s) by, for example, manipulating the various physical and chemical attributes of, for example, microshutter 60, microspring(s) 80, expansion beam element(s) 95, output beam element(s) 100, loop(s) 115, and also shifting the leverage point on lever(s) 110.

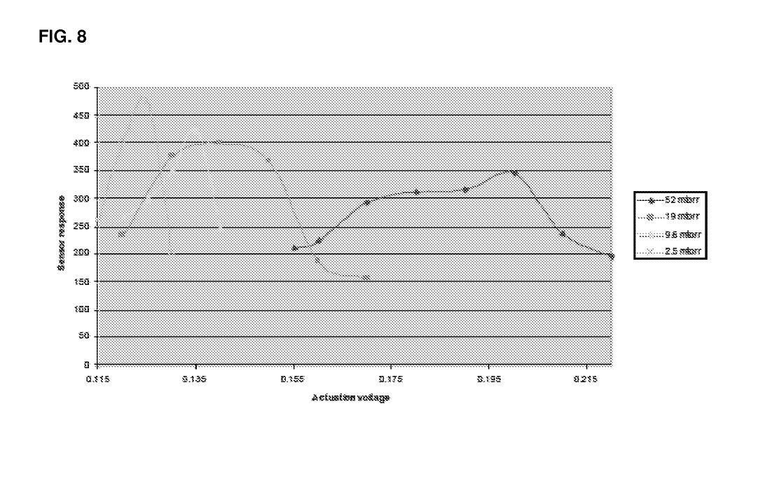

FIG. 8 illustrates observed variations in sensor response profile to varying microshutter actuation voltage under different vacuum conditions. For this particular illustration, the external field strength applied was 6000 V/m, the frequency of the actuation voltage applied is 2000 Hz, and the time constant and sensitivity of the lock-in amplifier used for processing sensor output were 1 second and 500 uV respectively. Evident from the graph, and consistent with the foregoing, a high vacuum condition (e.g. under 2.5 mTorr) enabled higher sensor response(s) at lower actuation voltage(s), while under a lower vaccum condition (e.g. under 52 mTorr), lower sensor responses were observed despite the application of higher actuation voltages. However, it should also be noted that although an increase in vacuum condition resulted in an increase in sensor response, same also rendered sensor response more variable to a given variation in actuation voltage. In other words, if the actuation voltage applied is subject to fluctuation, a high vacuum condition may not be optimal due to increased sensor variability, and a lower vacuum condition may be preferred albeit at a cost of reduced sensor sensitivity.

As described herein, an electrical potential sensor device comprises sensor electrodes arranged to measure a voltage based on a change in electrical charge induced in the sensor electrodes by exposure to an electrical potential of a source to be measured. An electro-thermally operated mechanism, adjacent to the sensor electrodes, is movable between a first position in which only first ones of the sensor electrodes are exposed to the electrical potential of the source to be measured and other sensor electrodes are shielded from the electrical potential, and a second position in which the other ones of the sensor electrodes are exposed to the electrical potential and the first ones are substantially shielded from the electrical potential. A controller combines the output from the two sets of electrodes which are alternately exposed to the electrical potential to calculate a resulting measured/sensed voltage or measured/sensed electrical potential of the device.

All publications, patents and patent applications referred to herein are incorporated by reference in their entirety to the same extent as if each individual publication, patent or patent application was specifically and individually indicated to be incorporated by reference in its entirety.

Having illustrated and described the principles of the invention in a preferred embodiment, it should be appreciated to those skilled in the art that the invention can be modified and/or varied in arrangement and detail without departure from such principles. Accordingly, it is intended to embrace all such modifications and/or variations that fall within the spirit and broad scope of the appended claims.

1. An electrical potential sensor device for measuring electrical potential of a source to be measured, the device comprising:
at least one sensor electrode arranged to measure a voltage based on a change in electrical charge induced in said at least one sensor electrode by exposure to the electrical potential of the source to be measured;
a mechanism adjacent to said at least one sensor electrode which is movable between a first position in which said at least one sensor electrode is exposed to the electrical potential of the source to be measured and a second position in which said at least one sensor electrode is substantially shielded from the electrical potential of the source to be measured in relation to the first position; and
at least one actuator arranged to operate the mechanism between the first and second positions;
said at least one actuator comprising an electrothermal actuator.

2. The device according to claim 1 wherein the electrothermal actuator of said at least one actuator comprises is an actuator which is responsive to a temperature differential.

3. The device according to claim 2 wherein the electrothermal actuator comprises an electrothermal actuator in which a temperature differential of the actuator is arranged to be induced by an alternating electrical current.

4. The device according to claim 1 wherein the mechanism comprises a movable shutter having openings therein, the openings being aligned with said at least one sensor electrode only in the first position of the mechanism.

5. The device according to claim 1 wherein there is provided at least one auxiliary sensor electrode arranged to measure the voltage based on a change in electrical charge induced in said at least one auxiliary sensor electrode by exposure to the electrical potential of the source to be measured, the mechanism being arranged such that only said at least one sensor electrode is exposed to the electrical potential of the source to be measured in the first position and such that only said at least one auxiliary sensor electrode is exposed to the electrical potential of the source to be measured in the second position.

6. The device according to claim 5 wherein the sensor electrodes which are arranged to be exposed to the electrical potential of the source to be measured in the first position are arranged to measure a first voltage and the sensor electrodes which are arranged to be exposed to the electrical potential of the source to be measured in the second position are arranged to measure a second voltage in which the first and second voltages are 180° out-of-phase with one other, and wherein there is provided a differential amplifier arranged to produce a single measured output voltage from the first and second voltages.

7. The device according to claim 1 wherein said at least one actuator comprises a pair of actuators supported on respective opposite sides of the mechanism.

8. The device according to claim 7 wherein the pair of actuators are electrically driven by respective oppositely phased alternating currents.

9. The device according to claim 1 wherein the mechanism is ungrounded.

10. The device according to claim 1 wherein the electrothermal actuator of said at least one actuator is coupled to the mechanism through a lever.

11. The device according to claim 10 wherein the lever is coupled to the mechanism by a loop member.

12. The device according to claim 11 wherein the lever and the mechanism are coupled to diametrically opposing sides of the loop member.

13. The device according to claim 1 wherein the electrothermal actuator comprises a bent beam electrothermal actuator.

14. The device according to claim 13 wherein the bent beam electrothermal actuator comprises a simple bent-beam electrothermal actuator.

15. The device according to claim 13 wherein the bent beam electrothermal actuator comprises a cascading bent-beam electrothermal actuator.

16. The device according to claim 13 wherein the electrothermal actuator comprises a plurality of bent beam electrothermal actuators in parallel with one another.

17. The device according to claim 1 wherein the mechanism and said at least one actuator are surrounded by an electromagnetic shield arranged to shield said mechanism and said at least one actuator from the electrical potential of the source.

18. The device according to claim 1 wherein said mechanism is housed in a vacuum chamber maintained at a vacuum pressure.

19. The device according to claim 1 wherein there is provided a processor arranged to determine an electric field of the source to be measured using the voltage measured by said at least one sensor electrode.

20. The device according to claim 1 wherein the mechanism is supported for movement relative to said at least one sensor electrode in a direction of movement of an output of the actuator.

21. An electric potential sensor device for measuring an electrical potential of a source to be measured, the sensor comprising:
at least one sensor electrode arranged for measuring an electric potential based on a change in electrical charge induced in said at least one sensor electrode by exposure to the electrical potential of the source to be measured;
a capacitor modulator arranged for modulating a coupling capacitance between said at least one sensor electrode and the electrical potential of the source to be measured; and
at least one actuator operatively associated with the capacitor modulator;
wherein said at least one actuator comprises an electrothermal actuator.
